(19) United States
(12) Patent Application Publication
(10) Pub. No.: US 2023/0274045 A1
(43) Pub. Date: Aug. 31, 2023

(54) BUILDING INFORMATION MODELING (BIM)-BASED INTELLIGENT DRAFTING METHOD FOR PREFABRICATED BUILDINGS

(71) Applicant: Qingdao University of Technology, Qingdao (CN)

(72) Inventors: Shujuan YANG, Qingdao (CN); Dehu YU, Qingdao (CN); Naihua YUE, Qingdao (CN); Weixiao XU, Qingdao (CN)

(73) Assignee: Qingdao University of Technology, Qingdao (CN)

(21) Appl. No.: 17/923,612

(22) PCT Filed: Jun. 11, 2021
(86) PCT No.: PCT/CN2021/099618

§ 371 Date: Nov. 7, 2022

(30) Foreign Application Priority Data
Jun. 9, 2021 (CN) 202110644768.2

(51) Int. Cl. G06F 30/13; G06F 30/20; G06K 7/14

(52) U.S. Cl. CPC G06F 30/13; G06F 30/20; G06K 7/1417

(57) ABSTRACT

A Building Information Modeling (BIM)-based intelligent drafting method for prefabricated buildings includes the following steps: step 1: extracting building model information; step 2: modeling the building model information, where Revit elements are divided into model elements, datum elements, and view-specific elements; step 3: extracting element management information based on a BIM model; step 4: extracting a sub-model view based on a BIM global model; step 5: performing BIM-based three-dimensional (3D) parametric modeling; and step 6: performing intelligent drafting for the prefabricated buildings: extracting structure information by an integrated platform for production, sales, and construction of the prefabricated buildings, extracting architectural, structural and mechanical electrical BIM models and generating drawings with a quick response (QR) code.

### CROSS REFERENCES TO THE RELATED APPLICATIONS

The application is the national phase entry of International Application No. PCT/CN2021/099618, filed on Jun. 11, 2021, which is based on and claims priority to Chinese patent application No. 202110644768.2, filed on Jun. 9, 2021, the entire contents of which are incorporated herein by reference.

### TECHNICAL FIELD

The present disclosure provides a Building Information Modeling (BIM)-based intelligent drafting method for prefabricated buildings and relates to the technical field of engineering design and drafting.

### BACKGROUND

BIM runs through the whole design cycle, including project feasibility study, three-dimensional model refining, and the preparation of construction drawings. If a suitable method to extract the required information can be found from the BIM model and assist in drafting based on the BIM model, the design quality and design efficiency can be improved, and data exchange between the BIM model and the management system can be realized.

### SUMMARY

In view of the above-mentioned defects of the prior art, the present disclosure proposes a BIM-based intelligent drafting method for prefabricated buildings.

The BIM-based intelligent drafting method for prefabricated buildings according to the present disclosure includes the following steps:

Step 1: Building model information is extracted by sequentially describing building geometric information with a unified hierarchy according to the Industry Foundation Classes (IFC) standard to form a standard extraction model. The parameters of the standard extraction model include a project, a zone, space, a site, a building, and a building storey.

Step 2: The building model information is modeled, where Revit elements are divided into model elements, datum elements, and view-specific elements.

The model elements include hosts and model components, the hosts include walls, floors, roofs, and ceilings, and the model components include stairs, windows, doors, and furniture.

The datum elements include grids, levels, and reference planes.

The view-specific elements include annotation elements and details. The annotation elements include text notes, tags, symbols, and dimensions. The details include detail lines, filled regions, and two-dimensional (2D) detail components.

Step 3: Element management information is extracted based on a BIM model by extracting information from the BIM model based on five major elements of target analysis. The five major elements are as follows.

Element management (i.e., initial extracted information), including specific extracted information.

Quality and safety management, including personnel information, equipment information, material information, and structure information. Personnel information includes training information and personnel quality. Equipment information includes models, sites, service life, and technical parameters. Material information includes sites, fire ratings, heat transfer coefficients, and materials. Structure information includes envelope structures, functional information, and quality levels.

Cost management, including quantities and cost information. The quantities include areas, volumes, levels, and quality, and the cost information includes unit prices and amounts.

Progress management, including a progress plan, a construction process, and resource information. The progress plan includes model stage information, nodes, and total construction duration. The construction process includes a process flow and new technology. The resource information includes the number of personnel, the number of materials, and the number of machines.

Environmental management, including site information and building performance information. The site information includes geological information, building flooring, and site components. The building performance information includes thermal resistance, visible light transmittance, and a solar heat gain coefficient.

Step 4: A sub-model view based on a BIM global model is extracted. A sub-model is a basis of process-oriented BIM information extraction and integration. Building lifecycle application software extracts data from the BIM global model through the sub-model and integrates a generated result with the BIM global model through the sub-model. The sub-model includes IfcProject. Information defined by the IfcProject includes default units, a world coordinate system, a coordinate space dimension, the precision of a floating point number used in geometric representations, and the direction of a true north defined by the world coordinate system. Step 4 includes the following implementation steps:

Step (1): Sub-model data is separated. The sub-model data is separated from global model data for extraction. The separation is achieved by two different mechanisms: separation through a reverse attribute of an entity and separation through access representation of an entity attribute in the sub-model view.

Step (2): Entity data is extracted. The sub-model view stores entity types used for information exchange, including subject entities and auxiliary entities, all of which are independently exchangeable.

Step (3): The sub-model data is extracted based on the following sub-steps:

(1): An entity dictionary structure is initialized, the sub-model view is read, and a list of entity types is generated.

(2): Each type in the list of entity types is traversed and a database for a corresponding database record is searched based on the entity type.

(3): A database record set is traversed, where each record corresponds to one entity instance and uses a globally unique identifier (GUID) as a primary key.

(4): An entity dictionary is searched for an entity based on the GUID because the current entity has been created in the previous process due to a complex reference relationship among IFC models. If the entity exists, the next record is processed. Otherwise, the entity is extracted according to the foregoing step, and the successfully extracted entity is added to the data dictionary.

(5): The step of deleting records in the database is skipped during data extraction. An access mode of the entity for the corresponding data record is marked during extraction.

Step (4): The sub-model data is integrated using the following sub-steps:

(1): The sub-model view is read, where the sub-model view records access modes of entity attributes.

(2): A list of entity instances that can be exchanged independently is created, the entity instances in the list are traversed, and the entity extracting process described in the foregoing step is executed.

(3): Data exchange between the BIM model and other auxiliary software is performed to derivate various types of evaluations and provide a quantitative basis for design optimization and solution selection by comparison.

Step 5: BIM-based three-dimensional (3D) parametric modeling is performed using the following sub-steps:

Step (1): All building information is expressed in a unified form in a building information model to realize integration and complete sharing of the building information.

Step (2): Conflict and collision checking and deviation correction on a parametric model is performed through relevant BIM inspection software, and all-around real-time inspection is performed on the constructed 3D model through virtual roaming.

Step (3): Progress and cost information is added to an inspected and qualified 3D model, and quality and safety management is performed by using a wireless radio frequency technology and an on-site Internet of Things (IoT) sensing device.

Step (4): Resource analysis, audit analysis, and five-dimensional (5D) construction simulation are performed.

Step 6: Intelligent drafting for the prefabricated buildings is performed. Structure information is extracted by an integrated platform for production, sales, and construction of the prefabricated buildings. Architectural, structural, and mechanical electrical BIM models are extracted. Drawings with a quick response (QR) code are generated.

Preferably, in step (1) of step 4, the separation through a reverse attribute of an entity is achieved by using a relational entity objectified in the BIM model and includes the following sub-steps: storing associated entities in an instance of the entity through reference and searching by the associated entities through the reverse attribute for an instance of the relational entity that stores the relationship. The reverse attribute of the entity is an interface called dynamically when needed and is not stored, and the sub-model is separated from the global model through the reverse attribute.

Preferably, in step (1) of step 4, the separation through access representation of an entity attribute in the sub-model view is achieved through the access mode of the entity attribute defined in the sub-model view to provide more flexible sub-model separation control and includes the following sub-steps: separating the sub-model at an entity attribute whose access mode is identified as Ignore; and when the sub-model is reintegrated, ignoring, by the entity attribute identified as Ignore, external modifications and retaining original data.

Preferably, in the extracting entity data in step (2) of step 4, an entity type corresponding to an attribute value of an entity is an independently exchanging entity or a resource entity. Explicit attributes of entities are extracted sequentially during entity data extraction. If the explicit attribute is a reference type, an algorithm for extracting the entity is recursively called.

Preferably, in step (2) of step 4, entity data Ifc Actor is extracted by the following steps:

(1) directly obtaining an attribute value of GlobalId;

(2) processing an attribute Owner History, which is an entity type, and skipping extracting a value of the attribute because an access mode of the attribute is set to Ignore in the sub-model view;

(3)-(5) directly obtaining attribute values of Name, Description, and Object Type; and

(6) processing an attribute TheActor and storing an instance of IfcPersonAndOrganization; suspending processing of Ifc Actor and reading an attribute of the instance of IfcPersonAndOrganization; processing attributes The Person and The Organization, which are entity types and are recursively called; processing an attribute Roles, which is a listing type and whose member is an instance of an IfcActorRole type; obtaining attribute values of Role, UserDefinedRole, and Description; successfully reading the instance of IfcPersonAndOrganization and returning a value of the instance to a suspended call, that is, assigning the value to the attribute TheActor of the IfcActor instance.

Preferably, in step 6, performing intelligent drafting for prefabricated buildings includes the following sub-steps:

(1) automatic drafting by the BIM model; (2) embedded parts modeling and embedded parts aided drafting; (3) BIM-based block automatic classification; (4) processing draft aided drafting; and (5) scanning the QR code to view the model.

Preferably, in step 6, by presetting the QR code in the drawings, personnel in all phases of design and construction view the intelligent demonstration of the prefabricated buildings by scanning the QR code.

The beneficial effects of the present disclosure are as follows: The BIM-based intelligent drafting method for prefabricated buildings according to the present disclosure assists in drafting based on the BIM model, such that the design quality and design efficiency can be improved and data exchange between the model and the management system can be realized.

### BRIEF DESCRIPTION OF THE DRAWINGS

FIG. 1 is a flowchart of the principle of the present disclosure;

FIG. 2 is a logical relationship diagram of IFC objects of the present disclosure;

FIG. 3 is a classification diagram of Revit model elements of the present disclosure;

FIG. 4 is a flowchart sub-model data extraction of the present disclosure;

FIG. 5 is a flowchart of sub-model data integration of the present disclosure;

FIG. 6 is an analysis diagram of BIM data exchange formats of the present disclosure;

FIG. 7 is a flowchart of centralized element management based on target analysis; and

FIG. 8 is an example diagram of intelligent drafting for prefabricated buildings of the present disclosure.

### DETAILED DESCRIPTION OF THE EMBODIMENTS

The technical solutions of the embodiments of the present disclosure are clearly and completely described below with reference to the accompanying drawings. The described embodiments are merely a part rather than all the embodiments of the present disclosure. All other embodiments obtained by those of ordinary skill in the art based on the embodiments of the present disclosure without creative efforts shall fall within the protection scope of the present disclosure.

### Embodiment 1

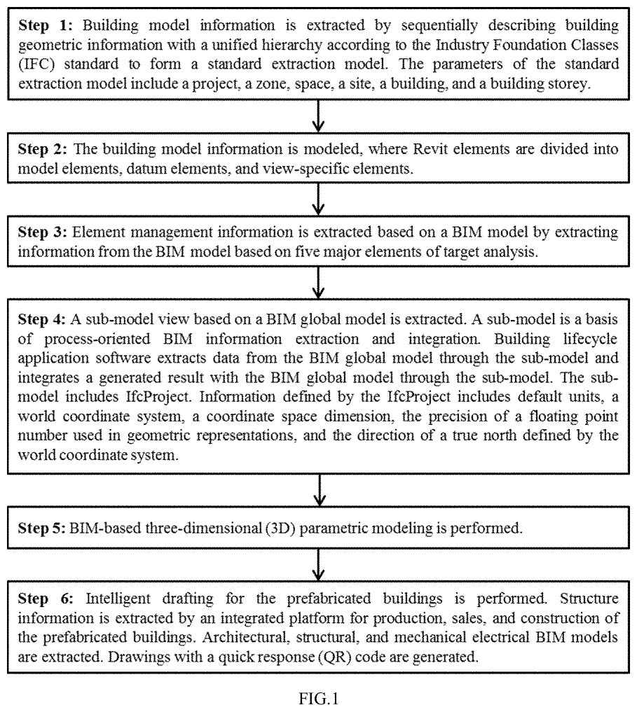

As shown in FIG. 1, the BIM-based intelligent drafting method for prefabricated buildings according to the present disclosure includes the following steps:

Step 1: Building model information is extracted by sequentially describing building geometric information with a unified hierarchy according to the IFC standard to form a standard extraction model. The parameters of the standard extraction model include a project, a zone, space, a site, a building, and a building storey.

Step 2: The building model information is modeled, where Revit elements are divided into model elements, datum elements, and view-specific elements.

The model elements include hosts and model components. The hosts include walls, floors, roofs, and ceilings, and the model components include stairs, windows, doors, and furniture.

The datum elements include grids, levels, and reference planes.

The view-specific elements include annotation elements and details. The annotation elements include text notes, tags, symbols, and dimensions, and the details include detail lines, filled regions, and 2D detail components.

Step 3: Element management information is extracted based on a BIM model. Information is extracted from the BIM model based on five major elements of target analysis. The five major elements include:

Element management (i.e., initial extracted information), including specific extracted information.

Quality and safety management, including personnel information, equipment information, material information, and structure information. Personnel information includes training information and personnel quality. Equipment information includes models, sites, service life, and technical parameters. Material information includes sites, fire ratings, heat transfer coefficients, and materials. Structure information includes envelope structures, functional information, and quality levels.

Cost management, including quantities and cost information. The quantities include areas, volumes, levels, and quality, and the cost information includes unit prices and amounts.

Progress management, including a progress plan, a construction process, and resource information. The progress plan includes model stage information, nodes, and total construction duration. The construction process includes a process flow and new technology. The resource information includes the number of personnel, the number of materials, and the number of machines.

Environmental management, including site information and building performance information. The site information includes geological information, building flooring, and site components, and the building performance information includes thermal resistance, visible light transmittance, and a solar heat gain coefficient.

Step 4: A sub-model view is extracted based on a BIM global model. A sub-model is a basis of process-oriented BIM information extraction and integration. Building lifecycle application software extracts data from the BIM global model through the sub-model and integrates a generated result with the BIM global model through the sub-model, which includes IfcProject. Information defined by the IfcProject includes default units, a world coordinate system, a coordinate space dimension, the precision of a floating point number used in geometric representations, and the direction of a true north defined by the world coordinate system. Step 4 includes the following implementation steps:

Step (1): separating sub-model data, where the sub-model data is separated from global model data for extraction, and the separation is achieved by two different mechanisms: separation through a reverse attribute of an entity and separation through access representation of an entity attribute in the sub-model view;

Step (2): extracting entity data, where the sub-model view stores entity types used for information exchange, including subject entities and auxiliary entities, all of which are independently exchangeable;

Step (3): extracting the sub-model data, including the following sub-steps:

(1): initializing an entity dictionary structure, reading the sub-model view, and generating a list of entity types;

(2): traversing each type in the list of entity types and searching a database for a corresponding database record based on the entity type;

(3): traversing a database record set, where each record corresponds to one entity instance and uses a GUID as a primary key;

(4): searching an entity dictionary for an entity based on the GUID because the current entity has been created in the previous process due to a complex reference relationship among IFC models; and if the entity exists, processing a next record; otherwise, extracting the entity according to the foregoing step and adding the successfully extracted entity to the data dictionary; and

(5): skipping deleting records in the database during data extraction, and marking an access mode of the entity for the corresponding data record during extraction; and

Step (4): integrating the sub-model data, including the following sub-steps:

(1): reading the sub-model view, where the sub-model view records access modes of entity attributes;

(2): creating a list of entity instances that can be exchanged independently, traversing the entity instances in the list, and executing the entity extracting process described in the foregoing step; and

(3): performing data exchange between the BIM model and other auxiliary software to derivate various types of evaluations and provide a quantitative basis for design optimization and solution selection by comparison.

Step 5: BIM-based 3D parametric modeling is performed and includes the following sub-steps:

step (1): expressing all building information in a unified form in a building information model to realize the integration and complete sharing of the building information;

step (2): performing conflict and collision checking and deviation correction on a parametric model through relevant BIM inspection software and performing an all-around real-time inspection on the constructed 3D model through virtual roaming;

step (3): adding progress and cost information to an inspected and qualified 3D model and performing quality and safety management by using a wireless radio frequency technology and an on-site Internet of Things (IoT) sensing device; and

step (4): performing resource analysis, audit analysis, and five-dimensional (5D) construction simulation; and

Step 6: Intelligent drafting for the prefabricated buildings is performed by: extracting structure information by an integrated platform for production, sales and construction of the prefabricated buildings, extracting architectural, structural and MEP BIM models, and generating drawings with a QR code.

### Embodiment 2

The present disclosure first imports a Revit model into unity3d, exports component information of each structure from the model, exports attribute information and coordinate information of each component to an Excel database, and finally imports the model data into a management system of a software platform, such that the data exchange between the model and the management system is realized through a unique ID associated with each component.

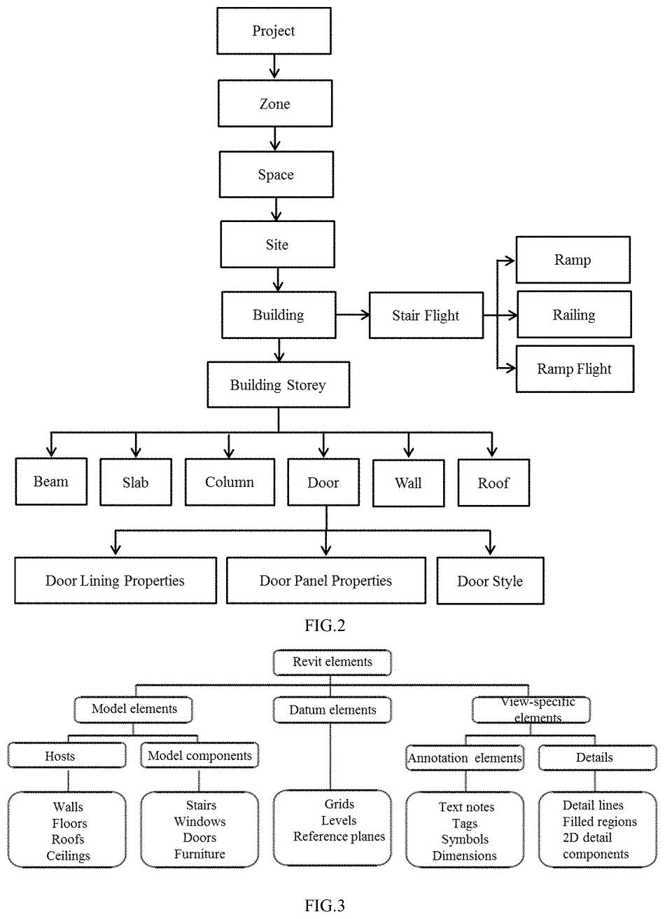

The essence of extracting the building model information is to identify various functional components and their related information. In the IFC standard, building geometric information is described in the sequence of a project (Ifc Project), a zone (Ifc Zone), space (Ifc Space), a site (Ifc Site), a building (Ifc Building), a building storey (Ifc Building Storey), and the like. The relationship between some objects in the IFC standard is described in FIG. 2.

The BIM model includes abundant information. As the mainstream of BIM modeling tools, the Revit model is used as an example in this specification. Element is the most basic class in Revit. There are mainly three types of elements: model elements, datum elements, and view-specific elements, as shown in FIG. 3.

The model elements represent the actual 3D geometry of the building, including hosts and model components. The datum elements help to define project context. The view-specific elements include annotation elements and details. The annotation elements are 2D components that document the model and maintain scale on paper, and the details are 2D items that provide details about the building model in a particular view.

Based on the above classification criteria, information can be extracted from the BIM model based on five major elements of target analysis, as shown in Table 1.

TABLE 1
Five types of element management information
extracted from the BIM model

| Element | Initial extracted | |
|---|---|---|
| management | information | Specific extracted information |
| Quality | Personnel information | Training information and |
| and safety | | personnel quality |
| management | Equipment information | Model, site, service life and |
| | | technical parameters |
| | Material information | Site, fire rating, heat transfer |
| | | coefficient and material |
| | Structure information | Envelope structure, functional |
| | | information and quality level |
| Cost | Quantities | Area, volume, level and quality |
| management | Cost information | Unit price and amount |
| Progress | Progress plan | Model stage information, nodes |
| management | | and total duration |
| | Construction process | Process and new technology |
| | Resource information | Quantity of personnel, quantity of |
| | | materials and quantity of machines |
| Environment | Site information | Geological information, building |
| management | | flooring and site component |
| | Building performance | Thermal resistance, visible light |
| | information | transmittance and solar heat gain |
| | | coefficient |

The BIM sub-model is a subset of the BIM global model, which is a BIM local model extracted from the BIM global model based on a sub-model view or generated by application software. In practical applications, sub-models are usually exchanged through STEP files or IFC XML files. The sub-model is a basis of process-oriented BIM information extraction and integration, and building lifecycle application software extracts data from the BIM global model through the sub-model and integrates the generated result with the BIM global model through the sub-model. The sub-model enables the applications to extract only relevant data, which can reduce the data transmission overheads of the network, reduce concurrent access to the data, maintain data consistency, and avoid data conflicts.

IfcProject defines the necessary global information and forms a necessary part of the sub-model. IfcProject has one and only one instance in the BIM global model, and information defined by its inheritance relationship includes default units, a world coordinate system, a coordinate space dimension, the precision of a floating point number used in geometric representations, and the direction of a true north defined by the world coordinate system. The information needs to be agreed upon among all parties involved before the project is implemented and should be kept read-only once created to avoid data inconsistencies and conflicts caused by differences in units and world coordinate systems.

Separation mechanisms for the sub-model data:

The sub-model data is separated from global model data for extraction, and the separation is achieved by two different mechanisms. One is a separation through a reverse attribute of an entity, and the other is a separation through access representation of an entity attribute in the sub-model view.

The first separation mechanism is achieved by using relational entities objectified in the BIM model. The relational entity (Ifc Relationship) provides a function similar to a relational table in a relational database and stores associated entities in an instance of the relational entity through reference, and the associated entities search through the reverse attribute for the instance of the relational entity that stores the relationship. The reverse attribute of the entity is an interface called dynamically when needed and is not stored. Therefore, the sub-model can be separated from the global model through the reverse attribute. The second separation mechanism is achieved through the access mode of the entity attribute defined in the sub-model view to provide a more flexible sub-model separation control. The sub-model is separated at an entity attribute whose access mode is identified as Ignore. When the sub-model is reintegrated, the entity attribute identified as Ignore ignores external modifications and retains original data. For example, for a derived entity of IfcProduct, the representation attribute that stores a geometric model does not need to be extracted in some applications. Usually, the geometry model occupies a large storage space, and separating the sub-model at this attribute can improve the extraction and transfer efficiency of the sub-model.

### Entity Data Extraction

The sub-model view stores entities used for information exchange, including subject entities and auxiliary entities, all of which are independently exchangeable. An entity type corresponding to an attribute value of an entity may be an independently exchanging entity or a resource entity. Explicit attributes of entities are extracted sequentially during entity data extraction. If the explicit attribute is a reference type, an algorithm for extracting the entity is recursively called. There are two termination conditions for a recursive call, either of which can be satisfied to terminate the recursive call process and return an interim result: 1) the attribute value is non-reference type or 2) the access attribute in the model view is Ignore.

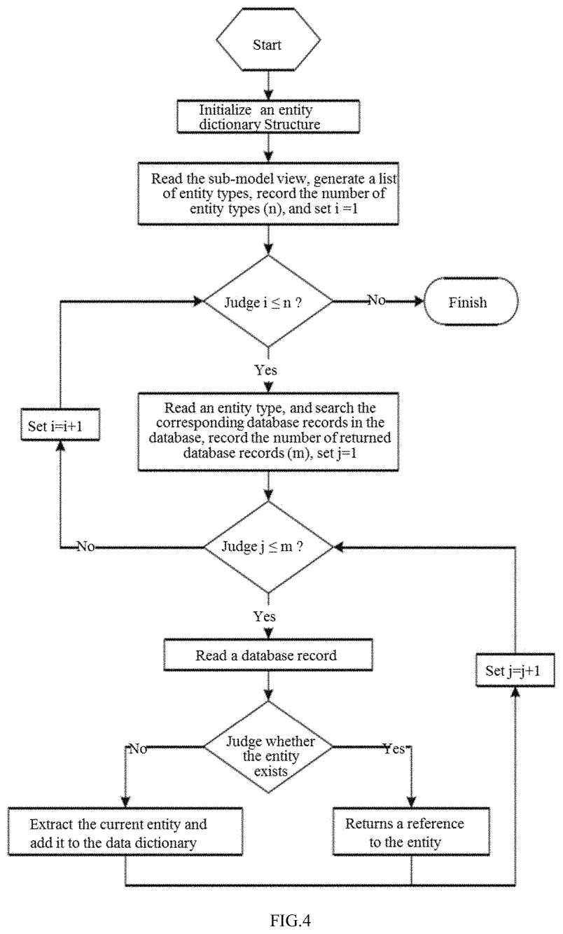

Ifc Actor entity is used as an example, and the extraction process is as shown in FIG. 4. Numbers in the gray boxes in the figure indicate the sequence of an algorithm call.

Step 1: Directly obtain an attribute value of GlobalId.

Step 2: Process an attribute Owner History, which is an entity type, and skip extracting a value of the attribute because an access mode of the attribute is set to Ignore in the sub-model view.

Steps 3-5: Directly obtain attribute values of Name, Description, and Object Type.

Step 6: Process an attribute TheActor, which is a selection type. In this embodiment, the selection type stores an instance of Ifc Person And Organization. In this case, the processing on Ifc Actor is suspended and an attribute of the instance of IfcPersonAndOrganization is read.

Step 6.1 and Step 6.2: Process attributes The Person and The Organization, which are entity types and are recursively called.

Step 6.3: Process an attribute Roles, which is a listing type and whose member is an instance of an IfcActorRole type.

Perform step 6.3.1 to step 6.3.3 to obtain attribute values of Role, UserDefinedRole, and Description. In this case, the instance of IfcPersonAndOrganization is successfully read and its value is returned to the suspended call, that is, its value is assigned to the attribute TheActor of the IfcActor instance. Extraction of the Ifc Actor instance is completed.

### The Extraction Process of Sub-Model Data

Due to the complex association relationship among IFC model entities, an entity instance may be referenced by multiple entity instances. During entity extraction, successfully extracted entities are stored in a dictionary structure with the GUID as the keyword to avoid duplicate extractions during entity extraction, which may cause data inconsistencies and conflicts. Before each entity extraction, the dictionary is retrieved to determine whether the entity has been extracted. If yes, the entity reference is directly obtained from the entity dictionary. Otherwise, the above entity extraction algorithm is called.

The extraction process of the sub-model data is as shown in FIG. 4. First, an entity dictionary structure is initialized, the sub-model view is read, and a list of entity types is generated. Then, each type in the list of entity types is traversed and a database is searched for a corresponding database record based on the entity type. A database record set is traversed, where each record corresponds to one entity instance and uses a GUID as a primary key. The current entity may have been created in the previous process due to the complex reference relationship among the IFC models. Therefore, an entity dictionary is searched for an entity based on the GUID. If the entity exists, the next record is processed. Otherwise, the entity is extracted as before and the successfully extracted entity is added to the data dictionary. Records in the database are not deleted during data extraction, and an access mode of the entity is marked for the corresponding data record during extraction.

The integration process of the sub-model data is as shown in FIG. 5. First, the sub-model view is read, and the sub-model view records access modes of entity attributes. Then, a list of entity instances that can be exchanged independently is created, the entity instances in this list are traversed, and the entity extracting process described in the foregoing step is executed.

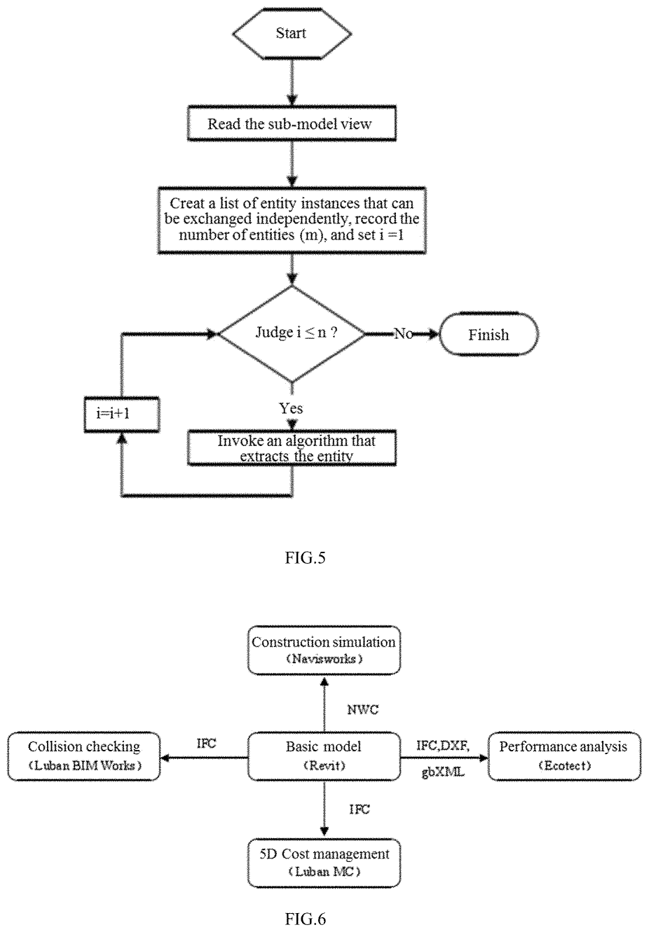

Data exchange between the BIM model and other auxiliary software is performed to derivate various types of evaluations and provide a quantitative basis for design optimization and solution selection by comparison. FIG. 6 analyzes the main exchange formats of the BIM model.

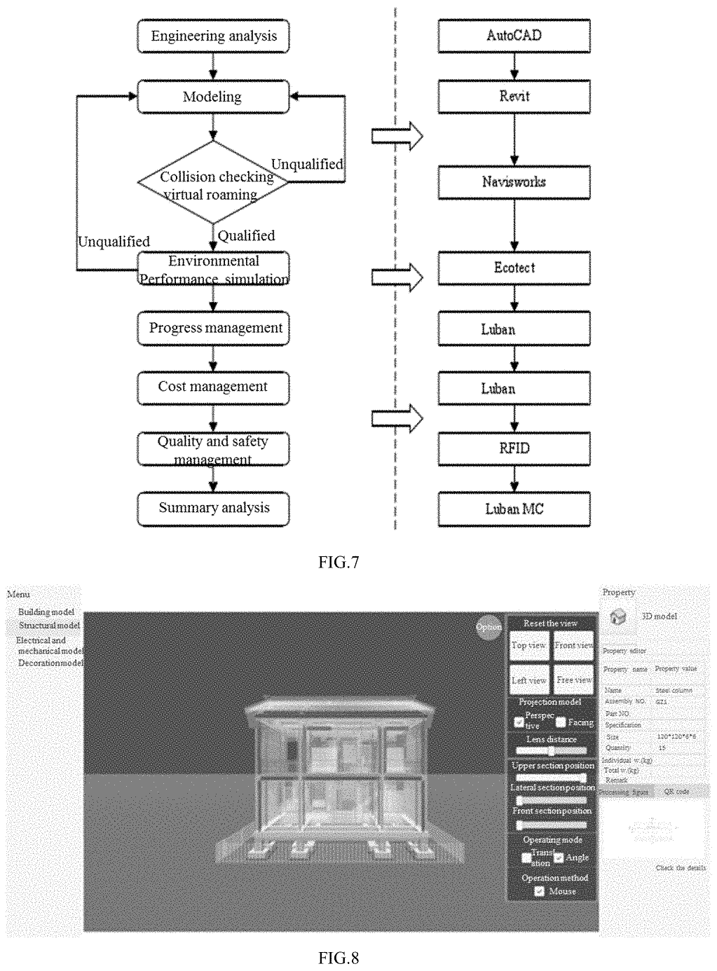

In this way, based on the initial 2D drawing analysis, the advanced 3D parametric modeling of the BIM technology is used to express all building information in a unified form in a building information model to realize the integration and complete sharing of the building information. Conflict and collision checking and deviation correction are performed on a parametric model through relevant BIM inspection software, and an all-around real-time inspection may be performed on the constructed 3D model through virtual roaming. Then progress and cost information is added to an inspected and qualified 3D model, and quality and safety management is performed by using a wireless radio frequency technology and an on-site IOT sensing device. Finally, resource analysis, audit analysis, and 5D construction simulation are performed. The element management process is shown in FIG. 7.

The extraction of structure information by an integrated platform for production, sales, and construction of the prefabricated buildings is shown in FIG. 8.

Architectural, structural, and electromechanical BIM model: The software pre-stores the architectural, structural, MEP, and decoration BIM model of each house type, and the model can be viewed and cut. When the building component is clicked, the related parameter information of the component is displayed in the attribute bar on the right, and the processing drawings and QR codes are displayed below. The QR code can be clicked to view the component information on the mobile phone.

The present disclosure can be widely used in engineering design and drafting.

It should be noted that relational terms herein, such as first and second are merely used to distinguish one entity or operation from another entity or operation without necessarily requiring or implying any actual such relationship or order between such entities or operations. In addition, the terms “include”, “comprise”, or any other variations thereof are intended to cover a non-exclusive inclusion so that a process, a method, an article, or a device including a series of elements not only includes those elements but also includes other elements that are not explicitly listed or also includes inherent elements of the process, the method, the article, or the device.

Although the embodiments of the present disclosure have been illustrated and described, it should be understood that those of ordinary skill in the art may make various changes, modifications, replacements, and variations to the above examples without departing from the principle and spirit of the present disclosure, and the scope of the present disclosure is limited by the appended claims and legal equivalents thereof.

What is claimed is:

1. A building information modeling (BIM)-based intelligent drafting method for prefabricated buildings, comprising:
step 1: extracting building model information: sequentially describing building geometric information with a unified hierarchy according to an Industry Foundation Classes (IFC) standard to form a standard extraction model, wherein parameters of the standard extraction model comprise a project, a zone, space, a site, a building, and a building storey;
step 2: modeling the building model information, wherein Revit elements are divided into model elements, datum elements, and view-specific elements;
the model elements comprise hosts and model components, the hosts comprise walls, floors, roofs, and ceilings, and the model components comprise stairs, windows, doors, and furniture;
the datum elements comprise grids, levels, and reference planes; and
the view-specific elements comprise annotation elements and details, the annotation elements comprise text notes, tags, symbols, and dimensions, and the details comprise detail lines, filled regions, and two-dimensional (2D) detail components;
step 3: extracting element management information based on a BIM model: extracting information from the BIM model based on five major elements of target analysis, wherein the five major elements comprise:
element management, wherein initial extracted information comprises specific extracted information;
quality and safety management comprising personnel information, equipment information, material information, and structure information, wherein the personnel information comprises training information and personnel quality; the equipment information comprises models, sites, service life, and technical parameters; the material information comprises sites, fire ratings, heat transfer coefficients, and materials; and the structure information comprises envelope structures, functional information, and quality levels;
cost management comprising quantities and cost information, wherein the quantities comprise areas, volumes, levels, and quality, and the cost information comprises unit prices and amounts;
progress management comprising a progress plan, a construction process, and resource information, wherein the progress plan comprises model stage information, nodes, and total construction duration; the construction process comprises a process flow and a new technology; and the resource information comprises a quantity of personnel, a quantity of materials, and a quantity of machines; and
environmental management comprising site information and building performance information, wherein the site information comprises geological information, building flooring, and site components, and the building performance information comprises thermal resistance, visible light transmittance, and a solar heat gain coefficient;
step 4: extracting a sub-model view based on a BIM global model, wherein a sub-model is a basis of process-oriented BIM information extraction and integration; building lifecycle application software extracts data from the BIM global model through the sub-model and integrates a generated result with the BIM global model through the sub-model; the sub-model comprises IfcProject; information defined by the IfcProject comprises default units, a world coordinate system, a coordinate space dimension, precision of a floating point number used in geometric representations, and a direction of a true north defined by the world coordinate system; and step 4 comprises the following implementation steps:
step (1): separating sub-model data, wherein the sub-model data is separated from global model data for extraction, and the separation is achieved by two different mechanisms: separation through a reverse attribute of an entity and separation through access representation of an entity attribute in the sub-model view;
step (2): extracting entity data, wherein the sub-model view stores entity types used for information exchange, comprising subject entities and auxiliary entities, and all of the subject entities and the auxiliary entities are independently exchangeable;
step (3): extracting the sub-model data by the following sub-steps:
(1): initializing a structure of an entity dictionary, reading the sub-model view, and generating a list of entity types;
(2): traversing each type in the list of entity types and searching a database for a corresponding database record according to an entity type;
(3): traversing a database record set, wherein each record corresponds to one entity instance and uses a globally unique identifier (GUID) as a primary key;
(4): searching, according to the GUID, the entity dictionary to determine whether an entity exists since a current entity has been created in the previous process due to a complex reference relationship among IFC models; and if the entity exists, processing a next record; if the entity does not exist, extracting the entity according to the foregoing step and adding the extracted entity to a data dictionary; and
(5): skipping deleting records in the database during data extraction and marking an access mode of the entity for a corresponding data record during the data extraction; and
step (4): integrating the sub-model data by the following sub-steps:
(1): reading the sub-model view, wherein the sub-model view records access modes of entity attributes;
(2): creating a list of entity instances allowed to be exchanged independently, traversing the entity instances in the list, and executing an entity extracting process described in the foregoing step; and
(3): performing data exchange between the BIM model and other auxiliary software to derivate various types of evaluations and provide a quantitative basis for design optimization and solution selection by comparison; and
step 5: performing BIM-based three-dimensional (3D) parametric modeling by the following sub-steps:
step (1): expressing all building information in a unified form in a building information model to realize integration and complete sharing of the building information;
step (2): performing conflict and collision checking and deviation correction on a parametric model through relevant BIM inspection software and performing an all-around real-time inspection on a constructed 3D model through virtual roaming;
step (3): adding progress and cost information to an inspected and qualified 3D model and performing quality and safety management by using a wireless radio frequency technology and an on-site Internet of Things (IoT) sensing device; and
step (4): performing resource analysis, audit analysis, and five-dimensional (5D) construction simulation; and
step 6: intelligently drafting for the prefabricated buildings, wherein an integrated platform for production, sales and construction of the prefabricated buildings extracts the structure information, extracts architectural, structural and mechanical electrical BIM models; and generates drawings with a quick response (QR) code.

2. The BIM-based intelligent drafting method for prefabricated buildings according to claim 1, wherein in step (1) of step 4, the separation through the reverse attribute of the entity is achieved by using a relational entity objectified in the BIM model and comprises the following sub-steps: storing an associated entity in an instance of the associated entity through reference, and searching, by the associated entity, for an instance of the relational entity that stores a relationship through the reverse attribute, wherein the reverse attribute of the entity is an interface required to be called dynamically and is not stored, and the sub-model is separated from the global model through the reverse attribute.

3. The BIM-based intelligent drafting method for prefabricated buildings according to claim 1, wherein in step (1) of step 4, the separation through the access representation of the entity attribute in the sub-model view is achieved through an access mode of the entity attribute defined in the sub-model view to provide more flexible sub-model separation control and comprises the following sub-steps: separating the sub-model at an entity attribute, wherein an access mode of the entity attribute is identified as Ignore; and when the sub-model is reintegrated, ignoring, by the entity attribute identified as Ignore, external modifications and retaining original data.

4. The BIM-based intelligent drafting method for prefabricated buildings according to claim 1, wherein in the extracting entity data in step (2) of step 4, an entity type corresponding to an attribute value of an entity is an independently exchanging entity or a resource entity, explicit attributes of entities are extracted sequentially during entity data extraction, and if the explicit attribute is a reference type, an algorithm for extracting the entity is recursively called.

5. The BIM-based intelligent drafting method for prefabricated buildings according to claim 1, wherein in step (2) of step 4, entity data Ifc Actor is extracted by the following steps:
(1) directly obtaining an attribute value of GlobalId;
(2) processing an attribute Owner History, wherein the attribute Owner History is an entity type, and skipping extracting a value of the attribute because an access mode of the attribute is set to Ignore in the sub-model view;
(3) directly obtaining attribute values of Name, Description, and Object Type; and
(4) processing an attribute TheActor and storing an instance of IfcPersonAndOrganization; suspending processing of IfcActor and reading an attribute of the instance of IfcPersonAndOrganization; processing attributes The Person and The Organization, wherein the attributes The Person and The Organization are entity types and are recursively called; processing an attribute Roles, wherein the attribute Roles is a listing type and a member of the listing type is an instance of an IfcActorRole type; obtaining attribute values of Role, UserDefinedRole and Description; successfully reading the instance of IfcPersonAndOrganization and returning a value of the instance to a suspended call, wherein the value is assigned to the attribute TheActor of the instance IfcActor.

6. The BIM-based intelligent drafting method for prefabricated buildings according to claim 1, wherein in step 6, the intelligently drafting for the prefabricated buildings comprises the following sub-steps:
(1) automatic drafting by the BIM model; (2) modeling of embedded parts and aided drafting of the embedded parts; (3) BIM-based block automatic classification; (4) aided drafting of a processing draft; and (5) scanning the QR code to view the BIM model.

7. The BIM-based intelligent drafting method for prefabricated buildings according to claim 1, wherein in step 6, by presetting the QR code in the drawings, personnel in all phases of design and construction view an intelligent demonstration of the prefabricated buildings by scanning the QR code.
